(19) United States
(12) Patent Application Publication
(10) Pub. No.: US 2007/0082505 A1
(43) Pub. Date: Apr. 12, 2007

(54) Method of forming an electrically insulating layer on a compound semiconductor

(75) Inventors: Jonathan K. Abrokwah, Chandler, AZ (US); Ravindranath Droopad, Chandler, AZ (US); Matthias Passlack, Chandler, AZ (US)

Correspondence Address: Kenneth A. Nelson;Bryan Cave LLP, Suite 2200, Two North Central Avenue, Phoenix, AZ, 85004-4406, US

(73) Assignee: Freescale Semiconductor, Inc., Austin, TX (US)

(21) Appl. No.: 11/248,923

(22) Filed: Oct. 11, 2005

(51) Int. Cl. H01L 21/31

(52) U.S. Cl. 438/778; 257/E21.207

(57) ABSTRACT

A method of forming an electrically insulating layer (130) on a compound semiconductor (110) comprises: providing a compound semiconductor structure; preparing an upper surface (111) of the compound semiconductor structure to be chemically clean; forming a template (120) on the compound semiconductor structure using a first precursor in a metalorganic chemical vapor deposition (MOCVD) system or a chemical beam epitaxy (CBE) system; and introducing oxygen and a second precursor to the MOCVD system in order to form the electrically insulating layer.

### FIELD OF THE INVENTION

This invention relates generally to electrically insulating layers in compound semiconductor electronics, and relates more particularly to a method of forming such electrically insulating layers in metalorganic chemical vapor deposition systems.

### BACKGROUND OF THE INVENTION

An ideal insulator capable of acting as a gate dielectric or an insulating passivation layer in GaAs and other compound semiconductor electronics would significantly improve the performance of both digital and analog manifestations of such electronics. As an example, the lower gate leakages that would be made possible by such an insulator would enhance an integration level of digital compound semiconductor electronics and would enhance RF performance of analog compound semiconductor electronics.

For many years, such an insulator was sought without success, due at least in part to a failure to identify a substance capable of unpinning the surface of compound semiconductors. More recently, some success has been achieved in molecular beam epitaxy (MBE) using E-beam and molecular beam sources of gallium oxide and gadolinium gallium oxide deposited onto a GaAs substrate, as disclosed, for example, in U.S. Pat. Nos. 6,159,834 and 6,756,320, which patents are incorporated herein by reference. However, an E-beam source produces ions and substrate damage at a level sufficient to create traps in the gallium oxide, which leads to an undesirable hysteresis in the frequency characteristics in the accumulation region. An MBE technique is also characterized by lower throughput and higher cost than a metalorganic chemical vapor deposition (MOCVD) process. MOCVD is particularly heavily used in optoelectronics as well as the manufacture of field effect transistors (FETs) and other compound semiconductors. Accordingly, there exists a need for a method of forming an electrically insulating layer on a compound semiconductor in an MOCVD system.

### BRIEF DESCRIPTION OF THE DRAWINGS

The invention will be better understood from a reading of the following detailed description, taken in conjunction with the accompanying figures in the drawings in which:

FIG. 1 is a simplified representation of a cross section of a portion of a compound semiconductor having an electrically insulating layer thereon in accordance with an embodiment of the invention; and

FIG. 2 illustrates a source for an MOCVD system for depositing an electrically insulating layer on compound semiconductors according to an embodiment of the invention.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner.

### DETAILED DESCRIPTION OF THE DRAWINGS

In one embodiment of the invention, a method of forming an electrically insulating layer on a compound semiconductor comprises: providing a compound semiconductor structure; preparing an upper surface of the compound semiconductor structure to be chemically clean; forming a template on the compound semiconductor structure using a first precursor in a metalorganic chemical vapor deposition system; and introducing oxygen and a second precursor to the metalorganic chemical vapor deposition system in order to form the electrically insulating layer.

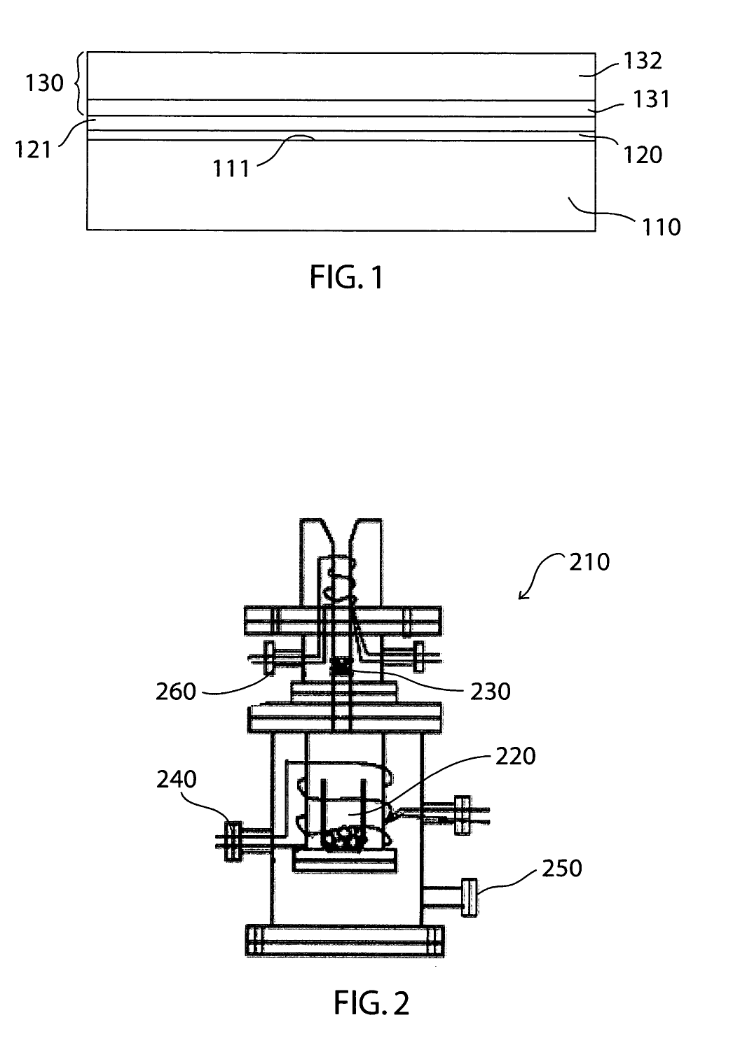

FIG. 1 is a simplified representation of a cross section of a portion of a compound semiconductor structure 110 having an electrically insulating layer 130 thereon that has been formed in accordance with an embodiment of the invention. As illustrated in FIG. 1, compound semiconductor structure 110 has an upper surface 111 on which is formed a template 120 in a manner to be described below. Electrically insulating layer 130 in the form of an insulating dielectric stack is formed above template 120 in a manner that will also be described below. As an example, a thickness of template 120 can be in a range of approximately 0.25 to 0.5 monolayers, which means template 120 is just a plane—less than approximately 0.2 nanometers.

As an example, compound semiconductor structure 110 may comprise a heterostructure such as a completed or partially completed semiconductor device. As a particular example, compound semiconductor structure 110 may comprise a GaAs heterojunction device such as a pseudomorphic high electron mobility transistor (PHEMT), a metal-oxide-semiconductor field effect transistor (MOSFET), a heterojunction bipolar transistor (HBT), a semiconductor laser, or the like.

As an example, the compound semiconductor may comprise a Group III-V compound, such as GaAs, InP, or the like, a Group IV compound such as SiGe or the like, or a Group II-VI compound such as HgCdTe or the like. In a particular embodiment, compound semiconductor structure 110 comprises a substance containing gallium and arsenic, such as GaAs, or a GaAs-based material. In that particular embodiment, template 120 comprises a substance containing gallium and oxygen, such as Ga₂O₃. Also in that particular embodiment, electrically insulating layer 130 comprises a substance containing gadolinium, gallium, and oxygen, such as (GdₓGa₁₋ₓ)₂O₃ or the like. In a different embodiment, electrically insulating layer 130 could be any chemically and mechanically stable oxide-based material with a high-dielectric constant and high band gap.

FIG. 2 illustrates a source for an MOCVD system in which an electrically insulating layer may be formed on a compound semiconductor according to an embodiment of the invention. The source uses a standard bubbler or sublimation cell 210 having a chamber 220 for holding a metal organic precursor, a needle valve 230, a connection 240 to a bulk heater (not shown), a connection 250 to a turbo pump (not shown), and a connection 260 to a conductance tube heater (not shown). The bulk heater, the turbo pump, and the conductance tube heater are components of an MOCVD system as known in the art. The MOCVD system also comprises additional components that, because they are well known, are not shown and not specifically referred to herein.

A flow rate from the precursor source may be adjusted to fit the requirements for depositing a desired composition. In general, the flow rate should be sufficient to produce a growth rate in a range of approximately 0.01 to 1.0 nanometers per second. The process may be performed at a standard low-pressure MOCVD pressure of approximately one atmosphere.

As an example, compound semiconductor structure 110 (see FIG. 1) may be prepared in the MOCVD system used to grow the semiconductor devices, with the system purged prior to the deposition of the oxide layer. Alternatively, a dual-chamber MOCVD system (not shown, but also well known in the art) may be used. In the dual-chamber MOCVD system, the epitaxial layers of the device structure are grown in a first semiconductor chamber and then the resulting wafer is transferred to an attached chamber having a sublimation cell that is used as a source for the oxide deposition. In either system, the next step is to purge the system of precursors, after which the substrate heating stage is brought to a temperature in a range of approximately 200 to 600 degrees Celsius. A first oxide precursor is then introduced into the MOCVD system from sublimation cell 210. Pyrolysis of the first precursor produces on surface 111 (see FIG. 1) of compound semiconductor structure 110 a template corresponding to template 120 in FIG. 1.

In one embodiment, the first precursor comprises a Ga₂O molecule and compound semiconductor structure 110 comprises a GaAs semiconductor. In that embodiment, the Ga₂O molecule, upon insertion into an As dimer row of the GaAs semiconductor, effectively unpins the Fermi level at surface 111 (see FIG. 1) thereby contributing to a low interfacial density of states. Template 120 is thus a key part of the successful formation of electrically insulating layer 130 (see FIG. 1).

Following the formation of template 120, oxygen in the form of O₂ gas is introduced into the MOCVD system in order to form one or more monolayers 121 of Ga₂O₃ on template 120. In one embodiment, monolayers 121 of Ga₂O₃, taken together, form a stack having a thickness in a range of approximately 0.5 to 5.0 nanometers. As an example, the stack can be made up of one to five monolayers, all of which are represented by layer 121 in FIG. 1. Monolayers 121 serve to maintain a stable interface with the semiconductor and to prevent subsequent Gd migration to the interface.

After the formation of monolayers 121 on template 120, and after a substrate heater (not shown) of the MOCVD system is brought to a temperature in a range of approximately 300 to 700 degrees Celsius, a second precursor is introduced from a second sublimation cell (not shown) that can be similar to sublimation cell 210 in order to form an electrically insulating layer corresponding to electrically insulating layer 130 (see FIG. 1). The formation of electrically insulating layer 130 is accomplished by pyrolysis of the second precursor.

In one embodiment the second precursor comprises a substance that contains gadolinium and oxygen. In another embodiment, the second precursor comprises a substance containing oxygen and gallium. As an example, the second precursor may comprise ethoxides of gallium or gadolinium. More generally, such ethoxides may be part of a family of alkoxides M(OR)₃, where M is metal and OR is a carbon-containing radical such as C₂H₅ or the like. The pyrolysis is governed by the reaction 2M(OR)₃=M₂O₃+ROH+Olefin. As known in the art, the olefin and the alcohol (ROH) are exhausted by the carrier gas of the MOCVD system.

Gadolinium and gallium ethoxides are solid compounds having low melting and boiling points (typically less than 200 degrees Celsius) and sublime at low temperatures. As further discussed below, such low temperatures offer advantages in terms of lowering contamination levels. Other possibilities for the second precursor include gadolinium and a substance containing oxygen and either gadolinium or gallium.

In one embodiment, and with reference again to FIG. 1, Ga₂O₃ is produced by pyrolysis of a 2Ga(OR)₃ precursor and formed as a lower layer 131 of electrically insulating layer 130. Pyrolysis of 2Gd(OR)₃ and 2Ga(OR)₃ precursors produces a (GdₓGa₁₋ₓ)₂O₃ oxide layer, which is formed as a layer 132 of electrically insulating layer 130. The resulting gadolinium gallium oxide (GGO) layer, corresponding to electrically insulating layer 130 and which as an example can be approximately 10 to 20 nanometers thick, provides a much better insulator than would Ga₂O₃ alone. In other embodiments, different Group III metals are used, with similar results.

The relatively low temperature ranges for sublimation cell 210 given above minimize extrinsic contamination levels. As an example, pyrolysis occurring in a temperature range of approximately 300 to 550 degrees Celsius produces little or no carbon contamination of the resulting oxide film. The low temperature process also helps to maintain a low interfacial density of states and produces an electrically insulating layer having low leakage, high electrical breakdown characteristics, good thermal and environmental stability, and high reliability, all of which make the insulated compound semiconductor structure attractive for electronic devices.

Although the foregoing discussion has focused on the formation of electrically insulating layers in an MOCVD system, an electrically insulating layer in accordance with an embodiment of the invention may also be formed in a chemical beam epitaxy (CBE) system, which systems are well known in the art. In a CBE system, sublimation cell 210 may be used for CBE growth in which an electrically insulating layer may be formed on a compound semiconductor according to an embodiment of the invention. A dual-chamber CBE system is preferable for such formation, where the semiconductor is grown in one chamber and then transferred to an attached oxide chamber in which oxide deposition takes place, similar to one of the embodiments described above in the MOCVD context. In a CBE system, a template corresponding to template 120 may be deposited by thermal evaporation of Ga₂O₃ in an effusion cell. The balance of the CBE process proceeds according to the steps outlined above for an MOCVD system.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the method discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A method of forming an electrically insulating layer on a compound semiconductor, the method comprising:
providing a compound semiconductor structure;
forming a template on the compound semiconductor structure using a first precursor in a metalorganic chemical vapor deposition system or a chemical beam epitaxy system; and
introducing a second precursor to the metalorganic chemical vapor deposition system or chemical beam epitaxy system in order to form the electrically insulating layer.

2. The method of claim 1 wherein:
the compound semiconductor is selected from the group consisting of: a Group III-V compound; a Group IV compound, and a Group II-VI compound.

3. The method of claim 1 wherein:
the template comprises a substance containing gallium and oxygen.

4. The method of claim 3 wherein:
the template comprises Ga₂O₃.

5. The method of claim 1 wherein:
the first precursor comprises a Ga₂O molecule.

6. The method of claim 1 wherein:
the second precursor comprises a substance containing oxygen and at least one of gadolinium or gallium.

7. The method of claim 6 wherein:
the second precursor comprises at least one of a gallium ethoxide and a gadolinium III ethoxide.

8. The method of claim 7 wherein:
the second precursor is one of a family of alkoxides in which a metal forms a chemical composition with (OC₂H₅)₃.

9. The method of claim 6 wherein:
the second precursor comprises Gd₂O.

10. The method of claim 1 wherein:
the electrically insulating layer comprises a substance containing gadolinium, gallium, and oxygen.

11. The method of claim 10 wherein:
the electrically insulating layer comprises GdGaO.

12. The method of claim 1 wherein:
a flow rate of the metalorganic chemical vapor deposition system is sufficient to produce a growth rate in a range of approximately 0.01 to 1.0 nanometers per second.

13. The method of claim 1 wherein:
forming the template comprises forming the template to have a thickness in a range of approximately 0.5 to 5 nanometers.

14. The method of claim 1 wherein:
forming the electrically insulating layer comprises forming the electrically insulating layer to have a thickness in a range of approximately 10 to 20 nanometers.

15. The method of claim 1 wherein:
forming the template comprises forming the template while the compound semiconductor structure is at a temperature in a range of approximately 200 to 600 degrees Celsius.

16. The method of claim 1 wherein:
introducing the second precursor to the metalorganic chemical vapor deposition system comprises introducing the second precursor while the compound semiconductor structure is at a temperature of at least approximately 300 degrees Celsius.

17. A method of forming an electrically insulating layer on a GaAs-based semiconductor structure, the method comprising:
providing a GaAs device in a metalorganic chemical vapor deposition chamber;
purging the metalorganic chemical vapor deposition chamber;
introducing a first precursor containing a Ga₂O molecule into the metalorganic chemical vapor deposition chamber in order to form a Ga₂O₃ template over an upper surface of the GaAs device in an oxygen environment; and
introducing oxygen and a second precursor containing gadolinium into the metalorganic chemical vapor deposition chamber in order to form the electrically insulating layer over the upper surface of the GaAs device.

18. The method of claim 17 wherein:
the second precursor comprises a substance containing Gd₂O.

19. The method of claim 17 wherein:
forming the Ga₂O₃ template comprises forming the Ga₂O₃ template while the GaAs device is at a temperature in a range of approximately 200 to 600 degrees Celsius; and
introducing the second precursor to the metalorganic chemical vapor deposition chamber comprises introducing the second precursor while the GaAs device is at a temperature in a range of approximately 300 to 700 degrees Celsius.

20. A method of forming an electrically insulating layer on a semiconductor structure, the method comprising:
providing a GaAs semiconductor having an upper surface;
using a metalorganic chemical vapor deposition system, inserting a Ga₂O molecule of a first precursor into an As dimer row of the GaAs semiconductor in order to unpin a Fermi level of the GaAs semiconductor;
using the first precursor to form a Ga₂O₃ template over the upper surface of the GaAs semiconductor;
introducing oxygen and a second precursor containing gadolinium into the metalorganic chemical vapor deposition system in order to form the electrically insulating layer over the upper surface of the GaAs semiconductor.
